(19) United States
(12) Patent Application Publication
(10) Pub. No.: US 2014/0191311 A1
(43) Pub. Date: Jul. 10, 2014

(54) SEMICONDUCTOR STRUCTURE AND METHOD FOR MANUFACTURING THE SAME

(71) Applicants: Lijun Dong, Beijing (CN); Dapeng Chen, Beijing (CN)

(72) Inventors: Lijun Dong, Beijing (CN); Dapeng Chen, Beijing (CN)

(73) Assignee: INSTITUTE OF MICROELECTRONICS, CHINESE ACADEMY OF SCIENCES, Beijing (CN)

(21) Appl. No.: 13/878,655

(22) PCT Filed: May 18, 2012
(86) PCT No.: PCT/CN2012/075738

§ 371 Date: Apr. 10, 2013

(30) Foreign Application Priority Data
May 2, 2012 (CN) 201210135261.5

(51) Int. Cl. H01L 29/78; H01L 29/66

(52) U.S. Cl. CPC H01L 29/78; H01L 29/66621
USPC 257/330; 438/270

(57) ABSTRACT

Provided is a semiconductor structure and a method for manufacturing the same. By the channel reestablishment, the tops of the source/drain regions located on both sides of the spacers are higher than bottoms of the gate stack structure and the spacers, and the source/drain regions laterally extend below the bottoms of the gate stack structure and the spacers and exceed the spacers, thereby reaching the right below of the gate stack structure. Thus, the elevated source/drain MOSFET is obtained. The semiconductor structure reduces the number of process steps, improves efficiency and decreases the cost.

### CROSS-REFERENCE TO RELATED PATENT APPLICATIONS

This application is a U.S. National Phase Application under 35 U.S.C. §371 of International Patent Application No. PCT/CN2012/075738, filed May 18, 2012, and claims the benefit of Chinese Patent Application No. 201210135261.5, filed on May 2, 2012, titled “SEMICONDUCTOR STRUCTURE AND METHOD FOR MANUFACTURING THE SAME” all of which are incorporated by reference herein in its entirety.

### FIELD OF THE INVENTION

The present invention relates to the field of semiconductor manufacturing, and particularly, to a semiconductor structure and a method for manufacturing the same.

### BACKGROUND OF THE INVENTION

The source/drain series resistance can be decreased by elevating the source/drain Metal Oxide Semiconductor Field Effect Transistor (MOSFET), so as to achieve better device characteristics. Generally, the elevated source/drain technology performs high concentration epitaxies in the source/drain expansion regions of n and p tubes through the selective epitaxial method, respectively. The two times of selective epitaxies greatly increase the process cost. In addition, the non-planar process caused by the epitaxies also brings difficulty to the subsequent lithography.

### SUMMARY OF THE INVENTION

Since the current method for manufacturing the elevated source/drain MOSFET has the disadvantages of high process cost and difficulty and low efficiency, the present invention proposes to obtain the elevated source/drain MOSFET by means of a channel reestablishment. This is a silicon planar process without requiring an SDE implantation, a spacer deposition or an epitaxy, thereby greatly reducing the cost and improving the efficiency.

According to one aspect of the present invention, a method for manufacturing a semiconductor structure is provided, the method comprising:

a) providing a substrate;

b) forming a dummy gate stack and source/drain regions on the substrate; wherein the dummy gate stack at least comprises a dummy gate; and the source/drain regions are located on both sides of the dummy gate stack and extend to right below of the dummy gate stack;

c) forming an interlayer dielectric layer that covers the substrate, the source/drain regions and the dummy gate stack;

d) removing a part of the interlayer dielectric layer to expose the dummy gate stack;

e) removing the dummy gate stack and a part of the substrate right below the dummy gate stack, so as to form an opening, right below which parts of the source/drain regions are reserved;

f) forming spacers attached to inner sidewalls of the opening; and

g) forming a gate dielectric layer at a bottom of the opening, and filling a conductive material to form a gate stack structure.

Another aspect of the present invention further provides a semiconductor structure, comprising:

a substrate;

a gate stack structure partially embedded into the substrate and spacers; and

source/drain regions formed in the substrate; wherein tops of the source/drain regions located on both sides of the spacers are higher than bottoms of the gate stack structure and the spacers, and the source/drain regions laterally extend below the bottoms of the gate stack structure and the spacers and exceed the spacers, thereby reaching right below of the gate stack structure.

The method proposed by the present invention obtains the elevated source/drain MOSFET through the channel reestablishment, thereby greatly reduces the process steps, improving the production efficiency and decreasing the cost.

### BRIEF DESCRIPTION OF THE DRAWINGS

Other features, objectives and advantages of the present invention will be more apparent by reading the detailed descriptions of the non-limited embodiments made with reference to the following drawings:

FIG. 1 is a flowchart of a method for manufacturing a semiconductor structure according to the present invention; and

FIGS. 2a to 7 are cross-sectional views of respective stages for manufacturing the semiconductor structure in accordance with the flow as illustrated in FIG. 1 according to one preferred embodiment of the present invention.

The same or similar parts are denoted with the same or similar reference signs in the drawings.

### DETAILED DESCRIPTION OF THE INVENTION

### Embodiments

The embodiments of the present invention are described in detail as follows. The examples of the embodiments are illustrated in the drawings. The embodiments described as follows with reference to the drawings are exemplary, and are merely used to interpret the present invention, rather than limiting the present invention,

The following disclosure provides many different embodiments or examples to implement different structures of the present invention. In order to simplify the disclosure of the present invention, the components and arrangements of specific examples are described in the following text. Apparently, they are just exemplary, and do not intend to restrict the present invention. In addition, reference numbers and/or letters can be repeated in different examples of the present invention for the purposes of simplification and clearness, without indicating the relationships between the discussed embodiments and/or arrangements. Furthermore, the present invention provides the examples of various specific processes and materials, but a person skilled in the art can realize the availability of other processes and/or usage of other material's. To be noted, the components as illustrated in the drawings are not always drawn to scale. In the present invention, the descriptions of known assemblies as well as processing techniques and processes are omitted, so as to avoid any unnecessary restriction to the present invention.

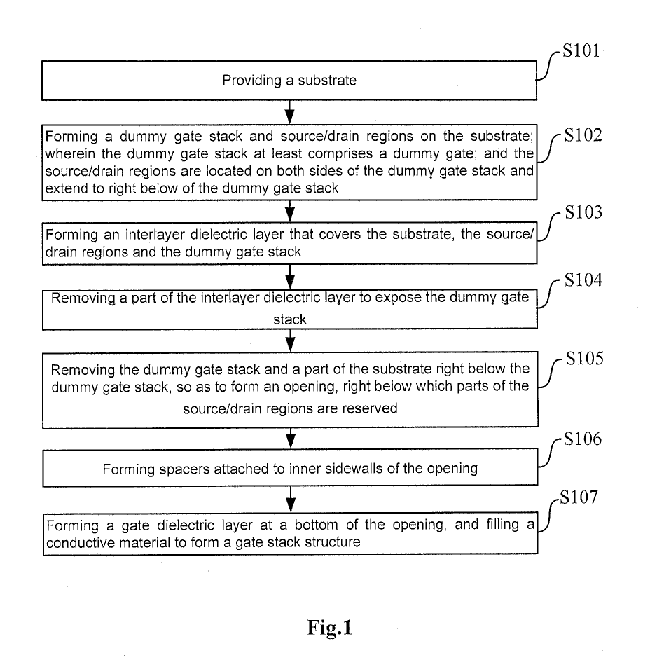

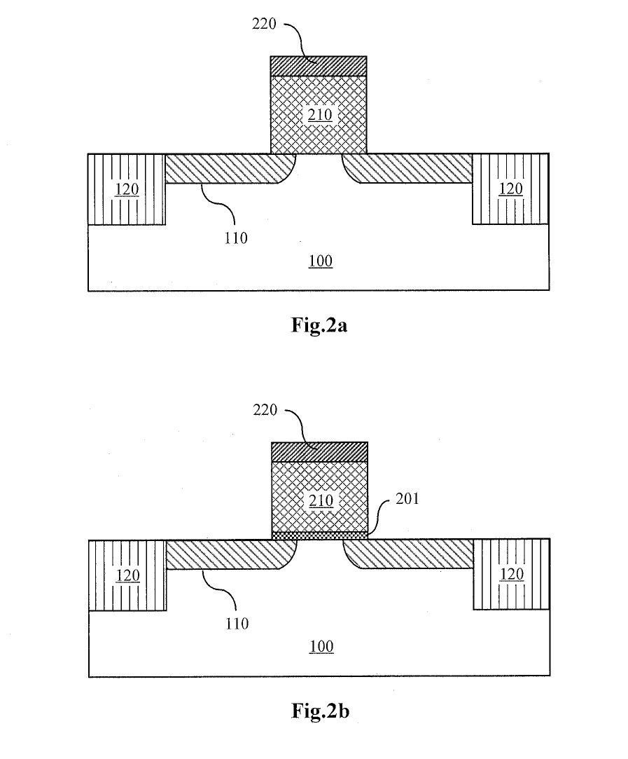

Next, the method for manufacturing a semiconductor structure as illustrated in FIG. 1 is described in detail with reference to FIGS. 2a to 7.

Referring to FIGS. 1, 2a and 2b, in step S101, a substrate 100 is provided.

In this embodiment, the substrate 100 comprises the silicon substrate (e.g., a silicon wafer). According to the design requirement known in the prior art (e.g., a P-type substrate or an N-type substrate), the substrate 100 may comprise various doped configurations. In other embodiments, the substrate 100 may further comprise other basic semiconductor such as germanium. Alternatively, the substrate 100 may comprise the compound semiconductors (e.g., III-V group materials) such as silicon carbide, gallium arsenide and indium arsenide. Typically, the semiconductor substrate 100 may have, but not limited to, a thickness of about several hundreds of microns, e.g., a thickness ranging from about 400 um to 800 um.

Specifically, isolation regions, such as shallow trench isolation (STI) structures 120, may be formed in the substrate 100, so as to electrically isolate the adjacent field effect transistor devices.

Referring to FIGS. 1, 2a and 2b, in step S102, a dummy gate stack and source/drain regions 110 are formed on the substrate 100. The dummy gate stack at least comprises a dummy gate 210. The source/drain regions 110 are located on both sides of the dummy gate stack and extend to right below of the dummy gate stack.

In this embodiment, the dummy gate stack comprises a dummy gate 210 and a cap layer 220, as illustrated in FIG. 2a. A gate dielectric layer is not available and it may be formed in the subsequent replacement gate process after the dummy gate stack is removed. During the formation of the dummy gate stack, the dummy gate 210 is formed with a thickness of about 10 nm to 80 nm by depositing for example Poly-Si, Poly-SiGe, amorphous silicon, and/or doped or undoped silicon oxide, silicon nitride, silicon oxynitride, silicon carbide or even metals on the substrate 100. Next, the cap layer 220 is formed on the dummy gate 210, for example, by depositing silicon nitride, silicon oxide, silicon oxynitride, or silicon carbide, or combinations thereof, for protecting a top of the dummy gate 210, and preventing the top of the dummy gate 210 from reacting with the deposited metal layer in the subsequent process of forming the contact layer. In other embodiments, the cap layer 220 may also not be formed. The dummy gate stack is formed by patterning through the photolithographic process and etching the deposited multi-layer structure using the etching process. In another embodiment, the dummy gate stack may also comprise a dummy gate dielectric layer 201, as illustrated in FIG. 2b, provided that during the formation of the dummy gate stack, the dummy gate dielectric layer 201 is firstly formed on the substrate 100 and then the above steps are repeated. The dummy gate dielectric layer 201 may be made of silicon oxide or silicon nitride, or a combination thereof. In other embodiments, the dummy gate dielectric layer 201 may also be made of high-k dielectrics, such as one of HfO₂, HfSiO, HfSiON, HfTaO, HfTiO, HfZrO, Al₂O₃, La₂O₃, ZrO₂ and LaAlO, or combinations thereof, with a thickness of about 2 nm to 10 nm.

Being different from the prior art in the process steps, the present invention does not form a spacer on the sidewall of the dummy gate stack after the dummy gate stack is formed.

The source/drain regions 110 are located on both sides of the dummy gate stack, and may be formed by implanting P-type or N-type dopants or impurities into the substrate 100. For example, for the PMOS, the source/drain regions 110 may be P-type doped, while for the NMOS, the source/drain regions 110 may be N-type doped. The source/drain regions 110 may be formed by means of lithography, ion implantation, diffusion and/or other appropriate process. The semiconductor structure is annealed using the general semiconductor processing technology and steps, so as to activate the dopants in the source/drain regions 110. The annealing may be rapid annealing, spike annealing or other appropriate methods. In this embodiment, firstly the dummy gate stack is formed, and then the source/drain implantation and annealing are carried out, so that the impurity ions are laterally diffused to obtain the source/drain regions extending to the right below of the dummy gate stack, as illustrated in FIGS. 2a and 2b. In another embodiment, firstly the source/drain regions are formed through lithography and implantation, and then a dummy gate stack is formed to cover the channel region between the source/drain regions and parts of the source/drain regions, thereby also obtaining the source/drain regions extending to the right below of the dummy gate stack. The source/drain regions located on both sides of the dummy gate stack may have a depth of about 50 nm to 100 nm, and the parts of the source/drain regions extending to the right below of the dummy gate stack may have a width of about 10 nm to 20 nm.

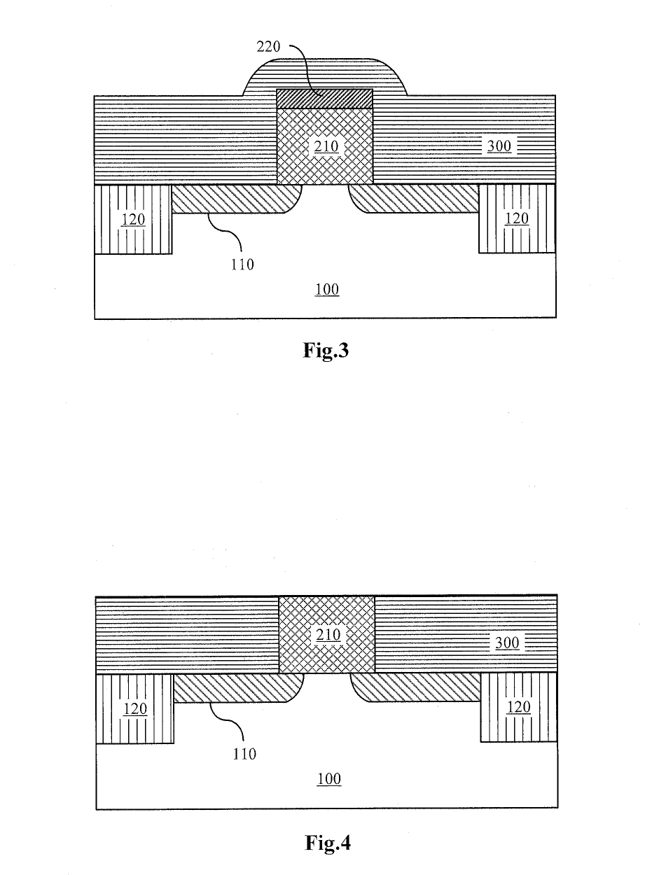

Referring to FIGS. 1 and 3, in step S103, an interlayer dielectric layer 300 is formed to cover the substrate 100, the source/drain regions 110 and the dummy gate stack. The interlayer dielectric layer 300 may be formed through Chemical Vapor Deposition (CVD), Plasma Enhanced Deposition CVD, High Density Plasma CVD, spin coating and/or other appropriate process. The interlayer dielectric layer 300 may be made of one of silicon oxide (USG), doped silicon oxide (e.g., fluorinated silicate glass, borosilicate glass, phosphosilicate glass and borophosphosilicate glass) and low k dielectric materials (e.g., black diamond and coral), or combinations thereof. The interlayer dielectric layer 300 may have a thickness ranging from about 40 nm to 150 nm, such as 80 nm, 100 nm or 120 nm, and may have a multi-layer structure (two adjacent layers may be made of different materials).

Referring to FIGS. 1 and 4, in step S104, a part of the interlayer dielectric layer 300 is removed to expose the dummy gate stack.

The replacement gate process is performed in this embodiment. Referring to FIG. 4, the interlayer dielectric layer 300 and the dummy gate stack are planarized to expose an upper surface of the dummy gate 210. For example, the interlayer dielectric layer 300 may be removed through a Chemical Mechanical Polishing (CMP) method, so that the upper surface of the dummy gate 210 is flush with that of the interlayer dielectric layer 300 (herein, the term “flush” means that a height difference between the two upper surfaces falls within a range allowed by the process error).

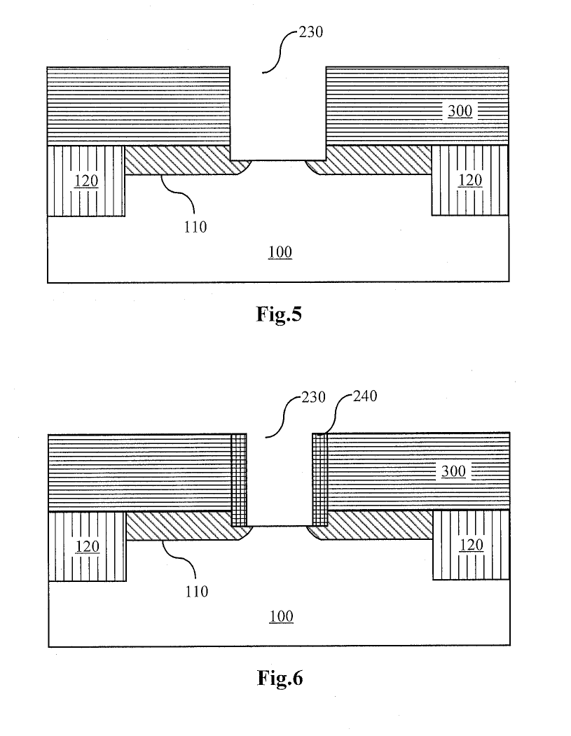

Referring to FIGS. 1 and 5, in step S105, the dummy gate stack and a part of the substrate right below the dummy gate stack are removed, so as to form an opening 230, right below which parts of the source/drain regions are reserved.

In this embodiment, the dummy gate 210 is removed firstly. In another embodiment, when the dummy gate stack comprises a dummy gate dielectric layer 201, the dummy gate 210 and the dummy gate dielectric layer 201 are together removed firstly. The dummy gate 210 or both the dummy gate 210 and the dummy gate dielectric layer 201 may be removed through a wet etching and/or a dry etching. The wet etching process uses tetramethylammonium hydroxide (TMAH), potassium hydroxide (KOH) or other solutions suitable for etching. The dry etching process uses hydrocarbons such as sulfur hexafluoride (SF₆), hydrogen bromide (HBr), hydrogen iodide (HI), chlorine, argon, helium, methane (and chloromethane), acetylene or ethylene, etc. or combinations thereof, and/or other appropriate materials. Next, a part of the substrate right below the dummy gate stack is removed to form the opening 230. The part of the substrate right below the dummy gate stack may be etched using different etching processes and/or different etchants. For example, when the part of the substrate to be etched is thin, the wet etching may be employed, and the wet etching process uses tetramethylammonium hydroxide (TMAH), potassium hydroxide (KOH) or other solutions suitable for etching.

In the embodiment of the present invention, as illustrated in FIG. 5, the depths of the etching channel and some source/drain regions shall be controlled, so that parts of the source/drain regions are reserved right below the opening 230. The size of the reserved source/drain regions can depend on the detailed design requirement. Specifically, when the part of the substrate right below the dummy gate stack is etched, the etching time may be prolonged or shortened. When the etching time is shortened, the reserved source/drain regions will have larger areas and thicknesses, and correspondingly, as can be seen from the subsequent step, the source/drain regions extending into the bottom of the gate stack are also larger and thicker. When the etching time is prolonged, the reserved source/drain regions will have smaller areas and thicknesses, and correspondingly, as can be seen from the subsequent step, the source/drain regions extending into the bottom of the gate stack are also smaller and thinner. A bottom of the opening 230 may be lower than the tops of the source/drain regions on both sides for a distance of about 10 nm to 50 nm.

Referring to FIGS. 1 and 6, in step S106, spacers 240 attached to inner sidewalls of the opening 230 are formed.

In this embodiment, after the opening 230 is formed, the spacers 240 are formed on the inner sidewall of the opening 230, so as to isolate the gate formed in the subsequent step. The spacers 240 may be made of silicon nitride, silicon oxide, silicon oxynitride or silicon carbide, or combinations thereof, and/or other appropriate materials. The spacers 240 may have a multi-layer structure, and two adjacent layers may be made of different materials. The spacers 240 may be formed by a process such as deposition etching, and the width thereof is not more than that of the reserved source/drain region right below the opening 230.

Referring to FIGS. 1, 6 and 7, in step S107, the bottom of the opening 230 is formed with a gate dielectric layer 250, and filled with a conductive material 260 to form a gate stack structure.

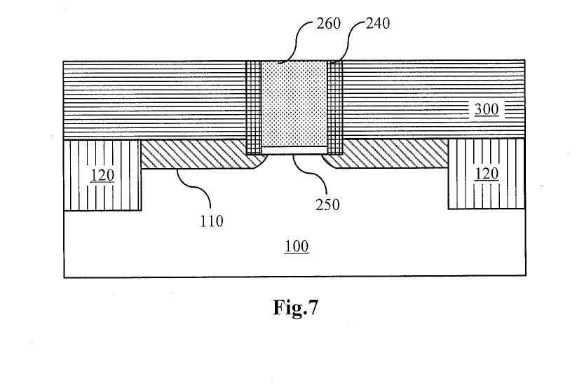

In this embodiment, after the spacers 240 are formed, the gate dielectric layer 250 is deposited to cover the bottom of the opening 230, as illustrated in FIG. 7. The gate dielectric layer 250 may be made of high-k dielectric, such as one of HfO₂, HfSiO, HfSiON, HfTaO, HfTiO, HfZrO, Al₂O₃, La₂O₃, ZrO₂ and LaAlO, or combinations thereof, with a thickness of about 2 nm to 10 nm, such as 5 nm or 8 nm. The gate dielectric layer 250 may be formed through a CVD or Atomic Layer Deposition (ALD) process. The gate dielectric layer 250 may also have a multi-layer structure, comprising more than two layers made of the above materials.

After the gate dielectric layer 250 is formed, an annealing is further performed to improve the performance of the semiconductor structure, and the annealing temperature ranges from about 600° C. to 800° C. After the annealing, a metal gate 260 is formed on the gate dielectric layer 250 by depositing the conductive material, thereby realizing a complete gate stack, as illustrated in FIG. 7. For the NMOS, the conductive material may be one of TaC, TiN, TaTbN, TaErN, TaYbN, TaSiN, HfSiN, MoSiN, RuTaₓ and NiTaₓ, or combinations thereof. For the PMOS, the conductive material may be MoNₓ, TiSiN, TiCN, TaAlC, TiAlN, TaN, PtSiₓ, Ni3Si, Pt, Ru, Ir, Mo, HfRu or RuOₓ. The thickness may be about 10 nm to 80 nm, such as 30 nm or 50 nm. In which, the metal gate 260 may also have a multi-layer structure, comprising more than two layers made of the above materials.

Referring to FIG. 7, which is a cross-sectional view of a semiconductor structure finally formed after the steps illustrated in FIG. 1 are performed. The semiconductor structure comprises a substrate 100; a gate stack structure partially embedded into the substrate 100 and spacers 240; and source/drain regions 110 formed in the substrate 100, Wherein, tops of the source/drain regions on both sides of the spacers 240 are higher than bottoms of the gate stack structure and the spacers 240 (herein the bottom of the gate stack structure refers to the interface between the gate stack, the sidewall spacer and the substrate 100). In addition, the source/drain regions 110 laterally extend below the bottoms of the gate stack structure and the spacers 240 and exceed the spacers 240, thereby reaching right below of the gate stack structure.

The bottom of the gate stack structure may be lower than the tops of the source/drain regions on both sides for a distance of about 10 nm to 50 nm.

The source/drain regions located on both sides of the gate stack structure may have a depth of about 50 nm to 100 nm

Although the exemplary embodiments and their advantages have been described in details, it shall be appreciated that various changes, replacements and modifications may be made to those embodiments without deviating from the spirit of the present invention and the protection scope defined in the accompanied claims. For other examples, a person skilled in the art will easily appreciate that the sequence of the process steps may be changed while maintaining the protection scope of the present invention.

Furthermore, the application scope of the present invention is not limited to the processes, structures, manufacturing, compositions, means, methods and steps of the specific embodiments as described in the specification. According to the disclosure of the present invention, a person skilled in the art will easily appreciate that when the processes, structures, manufacturing, compositions, means, methods and steps currently existing or to be developed in future are adopted to perform functions substantially the same as corresponding embodiments described in the present invention, or achieve substantially the same effects, a person skilled in the art can make applications of them according to the present invention. Therefore, the accompanied claims of the present invention intend to include these processes, structures, manufacturing, compositions, means, methods and steps within their protection scopes.

1. A method for manufacturing a semiconductor structure, comprising the steps of:
a) providing a substrate;
b) forming a dummy gate stack and source/drain regions on the substrate,
wherein the dummy gate stack at least comprises a dummy gate; and the source/drain regions are located on both sides of the dummy gate stack and extend to right below of the dummy gate stack;
c) forming an interlayer dielectric layer that covers the substrate, the source/drain regions and the dummy gate stack;
d) removing a part of the interlayer dielectric layer to expose the dummy gate stack;
e) removing the dummy gate stack and a part of the substrate right below the dummy gate stack, so as to form an opening, right below which parts of the source/drain regions are reserved;
f) forming spacers attached to inner sidewalls of the opening; and
g) forming a gate dielectric layer at a bottom of the opening, and filling a conductive material (260) to form a gate stack structure.

2. The method according to claim 1, wherein in step b), the source/drain regions extending to the right below of the dummy gate stack are obtained by firstly forming the dummy gate stack, and then performing a source/drain implantation and an annealing.

3. The method according to claim 1, wherein in step b), the source/drain regions extending to the right below of the dummy gate stack are obtained by firstly forming the source/drain regions, and then forming the dummy gate stack.

4. The method according to claim 1, wherein in step b), the parts of the source/drain regions extending to the right below of the dummy gate stack have a width of about 10 nm to 20 nm.

5. The method according to claim 1, wherein in step b), the source/drain regions located on both sides of the dummy gate stack have a depth of about 50 nm to 100 nm.

6. The method according to claim 1, wherein in step e), a size of the reserved parts of the source/drain regions is controlled by controlling etching time.

7. The method according to claim 1, wherein in step e), the bottom of the opening is lower than tops of the source/drain regions on both sides for about 10 nm to 50 nm.

8. The method according to claim 1, wherein in step f), a width of the spacers is not more than that of the parts of the source/drain regions reserved right below the opening.

9. A semiconductor structure, comprising:
a substrate;
a gate stack structure partially embedded into the substrate and spacers; and
source/drain regions formed in the substrate, wherein
tops of the source/drain regions located on both sides of the spacers are higher than bottoms of the gate stack structure and the spacers, and
the source/drain regions laterally extend below the bottoms of the gate stack structure and the spacers and exceed the spacers, thereby reaching right below of the gate stack structure.

10. The structure according to claim 9, wherein the bottom of the gate stack structure is lower than the tops of the source/drain regions on both sides for about 10 nm to 50 nm.

11. The structure according to claim 9, wherein the source/drain regions located on both sides of the gate stack structure have a depth of about 50 nm to 100 nm.
